(19) United States
(12) Patent Application Publication
(10) Pub. No.: US 2025/0191863 A1
(43) Pub. Date: Jun. 12, 2025

(54) MAGNETIC SWITCH DEVICE AND MAGNETIC SWITCH

(71) Applicant: Huizhou GATERON Electronic Technology Co.,Ltd, Huizhou (CN)

(72) Inventor: Daming WANG, Huizhou (CN)

(73) Assignee: Huizhou GATERON Electronic Technology Co.,Ltd, Huizhou (CN)

(21) Appl. No.: 18/969,326

(22) Filed: Dec. 5, 2024

(30) Foreign Application Priority Data
Dec. 8, 2023 (CN) 202323364623.0

(51) Int. Cl. H01H 36/00

(52) U.S. Cl. CPC H01H 36/00; H01H 2036/0086

(57) ABSTRACT

A magnetic switch device is provided. The magnetic switch device includes a magnetic switch, the magnetic switch includes a bottom case, an elastic member, a stem, a permanent magnet, and an upper case, a guide sleeve and a boss are arranged in the bottom case, the boss is set inside the guide sleeve.

### CROSS REFERENCE TO THE RELATED APPLICATIONS

This application is based upon and claims priority to Chinese Patent Application No. 202323364623.0, filed on Dec. 8, 2023, the entire contents of which are incorporated herein by reference.

### TECHNICAL FIELD

This disclosure relates to the field of switches, specifically to a magnetic switch device and a magnetic switch.

### BACKGROUND

The statements here only provide background information related to the present invention and do not necessarily constitute prior art.

The inventor realized that, in the existing magnetic switch device, the bottom case of the magnetic switch is mounted on the printed circuit board (PCB), the upper case is connected with the bottom case, the stem and the permanent magnet are mounted inside the upper case and the bottom case, and when in use, the permanent magnet moves down along with the stem by pressing the stem. When the Hall element senses a change in the magnetic field of the permanent magnet, it will switch the signal. And when the stem moves upwards to reset, the permanent magnet moves upwards along with the stem, the Hall element re-senses a change in the magnetic field of the permanent magnet and then switches the signal again.

The inventor realized that, the bottom of the bottom case corresponded to the permanent magnet installation position is empty. When pressed, the outer surface of the stem can be in sliding fit with the inner surface of the bottom case, and when the stem and the permanent magnet are pressed down, the lower side of the stem in the whole vertical movement stroke is suspended.

### SUMMARY

The disclosure provides a magnetic switch device, which includes a PCB and a magnetic switch, wherein the magnetic switch is connected with the PCB, the magnetic switch includes a bottom case, an elastic member, a stem, a permanent magnet and an upper case, a Hall element is installed on the PCB, the bottom end of the bottom case is connected to the PCB, a guide sleeve is arranged in the bottom case the elastic member is installed on the outer surface of the guide sleeve, the permanent magnet is connected to the bottom end of the stem, the bottom end of the stem sliding fit with the inner surface of the guide sleeve, and the stem abuts against the top end of the elastic member, the inner surface of the bottom case corresponding to the guide sleeve is enclosed, the upper case is connected to the bottom case the upper case is provided with a hole, so that the top end of the stem inserted into the hole, the outer surface of the stem is in contact with the upper case through the elastic member.

In some embodiments, a boss is provided on the inner surface of the bottom case corresponding to the guide sleeve.

In some embodiments, at least one sliding member is provided on the inner surface of the guide sleeve.

In some embodiments, the width of the sliding member on the side close to the guide sleeve is wider than the width on the side away from the guide sleeve.

In some embodiments, the cross-sectional area of the top end of the sliding member is smaller than the cross-sectional area of the bottom end.

In some embodiments, the number of the sliding member is set to four.

In some embodiments, an installation groove is formed in the bottom of the stem, and the permanent magnet is mounted in the installation groove.

In some embodiments, the Hall element is welded on the PCB.

In some embodiments, the elastic member is a spring.

In some embodiments the upper case is connected with the bottom case through a buckle structure.

In some embodiments, two protrusions are arranged at the bottom end of the bottom case, and two through holes are arranged on the PCB, and each protrusion is inserted into a through hole.

When the stem is pressed downwards, the bottom end of the stem slides down to drive the permanent magnet downwards, the Hall element senses the magnetic field change of the permanent magnet and switches the signal. When the user cancels the pressing force, the stem returns to its original position through the elastic member, the Hall element senses the magnetic field change again and switches the signal. The inner surface of the bottom case corresponding to the guide sleeve is enclosed, due to the cancellation of the opening on the bottom case, the stem, permanent magnet, guide sleeve, and inner surface of the bottom case form a cavity, the outer circumference of the stem slides in contact with the inner surface of the guide sleeve throughout the entire stroke, when the stem moves to the bottom of the magnetic switch, the lower side of the stem is limited by the inner surface of the bottom case, improved the stability of the magnetic switch throughout the entire pressing stroke, especially when the stem moves to the bottom, reduced the shaking of the stem, greatly improve the stability of the magnetic switch.

This disclosure also provides A magnetic switch device, including a PCB, a bottom case, an elastic member, a stem, a permanent magnet and an upper case, a Hall element is installed on the PCB, the bottom end of the bottom case is connected to the PCB, a guide sleeve and a boss are arranged in the bottom case, the guide sleeve is used to restrict the sliding direction of the stem, the boss is set inside the guide sleeve, the guide sleeve and the boss are spaced apart from each other, the bottom end of the elastic member is installed on the outer surface of the guide sleeve, the permanent magnet is connected to the bottom end of the stem, the bottom end of the stem sliding fit with the inner surface of the guide sleeve, and the stem abuts against the top end of the elastic member, the upper case is connected to the bottom case, the upper case is provided with a hole, and the top end of the stem is inserted into the hole, the outer surface of the stem is in contact with the upper case through the elastic member, and when the stem is pressed down, the permanent magnet comes into contact with the boss to make sound.

In some embodiments, the width of the top of the boss is less than the width of the bottom of the boss.

In some embodiments, the boss is set in one of the shapes of a circular truncated cone, a cylinder, a cone, a cube, or a pyramid.

In some embodiments, at least one sliding member is provided on the inner surface of the guide sleeve.

In some embodiments, the width of the sliding member on the side close to the guide sleeve is wider than the width on the side away from the guide sleeve.

In some embodiments, the cross-sectional area of the top end of the sliding member is smaller than the cross-sectional area of the bottom end.

In some embodiments, the number of the sliding member is set to four.

In some embodiments, the central line of the permanent magnet coincides with the central line of the boss.

In some embodiments, an installation groove is formed in the bottom of the stem, and the permanent magnet is mounted in the installation groove.

In some embodiments, the bottom end face of the permanent magnet is located in the installation groove, and the distance from the bottom end face of the permanent magnet to the bottom end face of the stem is less than the thickness of the boss.

When the stem is pressed downwards, the bottom end of the stem slides down to drive the permanent magnet downwards, the Hall element senses the magnetic field change of the permanent magnet and switches the signal, when the user cancels the pressing force, the stem returns to its original position through the elastic member, the Hall element senses the magnetic field change again and switches the signal.

When the permanent magnet reaches the bottom, the bottom end of the permanent magnet is against the top of the boss, and the permanent magnet collides with the boss to make a sound. The permanent magnet is made of metal, and the boss is made of plastic, the metal and the plastic collide can produce crisp sounds. The sound source vibrates inside the cavity and forms an echo phenomenon, a crisp sound is emitted inside the cavity, and the magnetic switch produces a crisp sound when pressed during use, effectively increasing the feedback of the magnetic switch.

This disclosure also provides a magnetic switch, including a bottom case, an elastic member, a stem, a permanent magnet and an upper case, a guide sleeve is arranged in the bottom case, the bottom end of the elastic member is installed on the outer surface of the guide sleeve, the permanent magnet is connected to the bottom end of the stem, the bottom end of the stem sliding fit with the inner surface of the guide sleeve and the stem abuts against the top end of the elastic member, the inner surface of the bottom case corresponding to the guide sleeve is enclosed, the upper case is connected to the bottom case, the upper case is provided with a hole, so that the top end of the stem is inserted into the hole, the outer surface of the stem is in contact with the upper case through the elastic member.

In some embodiments, a boss is provided on the inner surface of the bottom case corresponding to the guide sleeve.

In some embodiments, at least one sliding member is provided on the inner surface of the guide sleeve.

In some embodiments, the width of the sliding member on the side close to the guide sleeve is wider than the width on the side away from the guide sleeve.

In some embodiments, the cross-sectional area of the top end of the sliding member is smaller than the cross-sectional area of the bottom end.

In some embodiments, the number of the sliding member is set to four.

In some embodiments, an installation groove is formed in the bottom of the stem, the permanent magnet is mounted in the installation groove.

In some embodiments, the elastic member is a spring.

In some embodiments, the upper case is connected with the bottom case through a buckle structure.

In some embodiments, two protrusions are arranged at the bottom end of the bottom case.

### BRIEF DESCRIPTION OF THE DRAWINGS

FIG. 1 is a schematic diagram of a magnet switch device according to some embodiments

FIG. 2 is an exploded schematic diagram of a magnet switch device according to some embodiments

FIG. 3 is a sectional schematic diagram of a magnet switch device according to some embodiments

FIG. 4 is a top view schematic diagram of a magnet switch device according to some embodiments

FIG. 5 is an exploded schematic diagram of the stem and the permanent magnet according to some embodiments

FIG. 6 is an exploded schematic diagram of a part of a magnet switch device according to some embodiments

10—magnet switch device, 100—the bottom case, 110—guide sleeve, 120—boss, 130—sliding member, 200—elastic member, 300—stem, 400—permanent magnet, 500—upper case

### DETAILED DESCRIPTION OF THE EMBODIMENTS

The following discloses various implementation methods or embodiments. To simplify the disclosure, specific examples of each element and arrangement are described below. Of course, these are only examples and do not limit the scope of protection of the present invention. For example, if the first feature described in the specification is formed above or on top of the second feature, it may include embodiments in which the first and second features are directly connected, or embodiments in which additional features are formed between the first and second features, so that the first and second features may not be directly connected. In addition, these public contents may repeat the accompanying symbols and/or letters in different examples. This repetition is for the sake of simplicity and clarity, and does not in itself imply the relationship between the various embodiments and/or structures to be discussed. Furthermore, when the first element is described as being connected or combined with the second element, the description includes embodiments where the first and second elements are directly connected or combined with each other, as well as the use of one or more other intervening elements to indirectly connect or combine the first and second elements.

### Embodiment 1

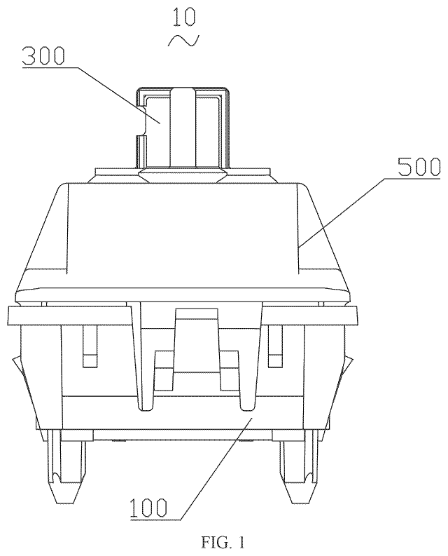

Referring to FIG. 1 to FIG. 6, this embodiment provides a magnetic switch device 10, which includes a PCB and a magnetic switch. The magnetic switch and the PCB are connected, the magnetic switch includes a bottom case 100, an elastic member 200, a stem 300, a permanent magnet 400 and an upper case 500, a Hall element is installed on the PCB, the bottom end of the bottom case 100 is connected to the PCB, a guide sleeve 110 is arranged in the bottom case 100 for restricting the sliding direction of the stem 300, a boss 120 is arranged in the bottom case 100, the boss 120 is set inside the guide sleeve 110, the guide sleeve 110 and the boss 120 are spaced apart from each other, the boss 120 is provided on the inner surface of the bottom case 100 corresponding to the guide sleeve 110, the elastic member 200 is installed on the outer surface of the guide sleeve 110, the bottom end of the elastic member 200 is installed on the outer surface of the guide sleeve 110, the permanent magnet 400 is connected to the bottom end of the stem 300, the bottom of the stem 300 sliding fit with the inner surface of the guide sleeve 110, and the stem 300 abuts against the top end of the elastic member 200, the inner surface of the bottom case 100 corresponding to the guide sleeve 110 is enclosed, the stem 300, permanent magnet 400, guide sleeve 110, and inner surface of the bottom case 100 form a cavity, the upper case 500 is connected to the bottom case 100, the upper case 500 is provided with a hole, so that the top end of the stem 300 is inserted into the hole, the outer surface of the stem 300 is in contact with the upper case 500 through the elastic member 200.

The outer circumference of the stem 300 slides in contact with the inner surface of the guide sleeve 110 throughout the entire stroke, when the stem 300 moves to the bottom of the magnetic switch. The lower side of the stem 300 is limited by the inner surface of the bottom case 100, which improved the stability of the magnetic switch throughout the entire pressing stroke, especially when the stem 300 moved to the bottom, reduced the shaking of the stem 300, and greatly improved the stability of the magnetic switch.

Additionally, when the stem 300 is pressed downwards, the permanent magnet 400 comes into contact with the boss 120 to make sound. The permanent magnet 400 is made of metal, and the boss 120 is made of plastic, the metal and the plastic collide can produce crisp sounds.

The Hall element is welded on the PCB (not shown in the attached figure), two protrusions are arranged at the bottom end of the bottom case 100, and two through holes are arranged on the PCB, and each protrusion is inserted into a through hole. So that completes the installation of the PCB and the bottom case 100, the height of the guide sleeve 110 is higher than the height of the boss 120, and the boss 120 is set up in correspondence with the permanent magnet 400.

The cross-sectional area of the boss 120 is smaller than the cross-sectional area of the permanent magnet 400, so that the contact area of the two is small, and the sound produced by the contact between the two is more crisp.

The bottom end of the elastic member 200 is installed on the outer surface of the guide sleeve 110. The upper part of the elastic member 200 is sleeved on the stem 300, and the upper case 500 is provided with a hole. The shape of the hole matches the shape of the top of the stem 300. The top end of the stem 300 is inserted into the hole. The elastic member 200 is used to clamp the stem 300 inside the upper case 500 under normal conditions, and make the top of the stem 300 protrude from the hole of the upper case 500. When the force pressing the stem 300 disappears, the elastic member 200 drives the stem 300 to return to its original position.

The upper case 500 is connected with the bottom case 100 through a buckle structure, and the permanent magnet 400 is connected to the bottom end of the stem 300. The position of the permanent magnet 400 and the Hall element is set accordingly, so that the permanent magnet 400 and the Hall element can be induced. The bottom end of the stem 300 sliding fit with the inner surface of the guide sleeve 110, the outer surface of the stem 300 is equipped with a sleeve, which is clamped inside the upper case 500 through the elastic member 200.

When the stem 300 is pressed downward, the bottom end of the stem 300 slides down to drive the permanent magnet 400 downward. The Hall element senses the magnetic field change of the permanent magnet 400 and switches the signal.

When the permanent magnet 400 reaches the bottom, the bottom end of the permanent magnet 400 is against the top of the boss 120, and the permanent magnet collides with the boss to make a sound. The permanent magnet 400 is made of metal, and the boss 120 is made of plastic, the metal and the plastic collide can produce crisp sounds.

When the user cancels the pressing force, the stem returns to its original position through the elastic member, the Hall element senses the magnetic field change again, and switches the signal.

The inner surface of the bottom case 100 corresponding to the guide sleeve 110 is enclosed, due to the cancellation of the opening on the bottom case. The stem 300, permanent magnet 400, guide sleeve 110, and inner surface of the bottom case 100 form a cavity. The sound source vibrates inside the cavity and forms an echo phenomenon, a crisp sound is emitted inside the cavity, and the magnetic switch produces a crisp sound when pressed during use, effectively increasing the feedback of the magnetic switch.

The outer circumference of the stem 300 slides in contact with the inner surface of the guide sleeve 110 throughout the entire stroke, when the stem 300 moves to the bottom of the magnetic switch. The lower side of the stem 300 is limited by the inner surface of the bottom case 100, which improved the stability of the magnetic switch throughout the entire pressing stroke, especially when the stem 300 moved to the bottom, reduced the shaking of the stem, and greatly improved the stability of the magnetic switch.

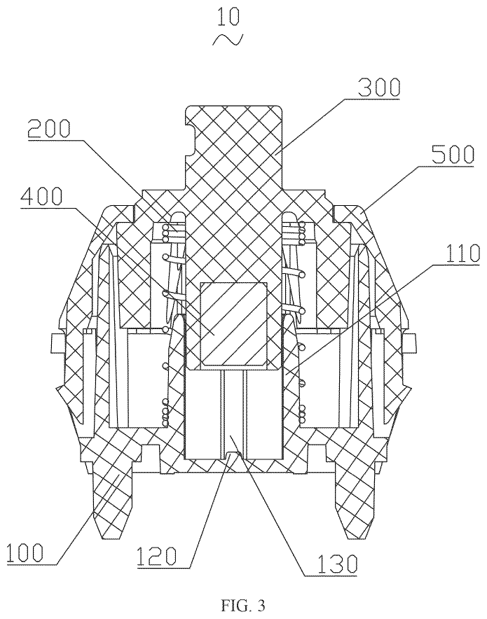

Referring to FIG. 3, the width of the top of the boss 120 is less than the width of the bottom of the boss 120. The width of the top end of the boss 120 is set smaller.

In some embodiments, the width of the top end of the boss 120 is equal to the width of the bottom end.

In some embodiments, the boss 120 is set in one of the shapes of a circular truncated cone, a cylinder, a cone, a cube or a pyramid.

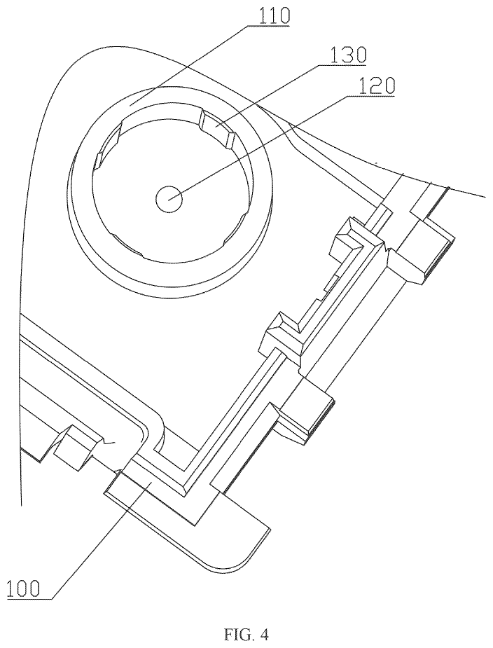

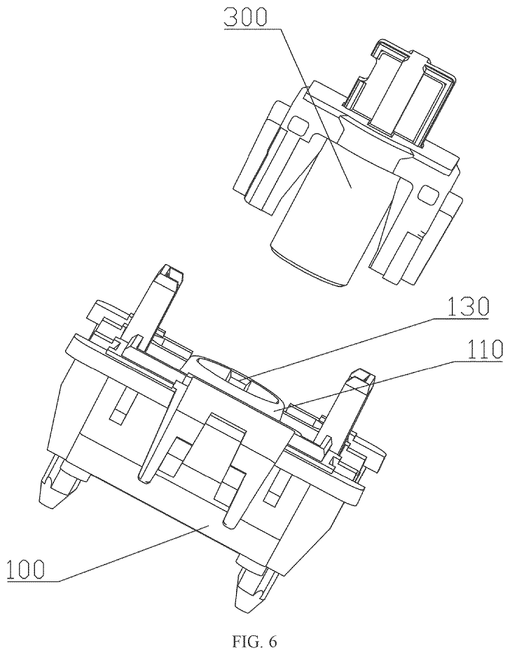

Referring to FIG. 3, FIG. 4 and FIG. 6, in order to make the magnetic switch device 10 smoother when in use, the inner surface of the guide sleeve 110 is provided with sliding members 130 for reducing the friction when in contact with the stem 300.

In some embodiments, the sliding member 130 is the rib. The rib and the stem 300 are correspondingly arranged to reduce the contact area between the bottom end of the stem 300 and the inner surface of the guide sleeve 110. The friction is reduced by the sliding member 130, when the stem 300 moves, the movement process is smoother and increases the user experience.

Referring to FIG. 3 and FIG. 4, the width of the slider member 130 on the side close to the guide sleeve 110 is wider than the width on the side away from the guide sleeve 110, aiming to further reduce friction.

By reducing the width of the side that is away from the guide sleeve 110, the contact area between the bottom end of the stem 300 and the inner surface of the guide sleeve 110 is reduced, in this way, the friction is further reduced.

In some embodiments, the width of the side of the sliding member 130 close to the guide sleeve 110 is equal to the width of the side away from the guide sleeve 110.

Referring to FIG. 4 and FIG. 6, the cross-sectional area of the top end of the sliding member 130 is less than the cross-sectional area of the bottom end, which improves the stability of the movement of the stem 300.

In some embodiments, referring to FIG. 4, the number of the sliding members 130 is set to four. The four ribs are evenly distributed on the inner surface of the guide sleeve 110 in the circumferential direction, so that the sliding is more stable.

In some embodiments, the number of the sliding members 130 is set to three.

In some embodiments, the number of the sliding members 130 is set to five.

The number of sliding members 130 is subject to the actual demand.

Referring to FIG. 4, the central line of the permanent magnet 400 coincides with the central line of the boss 120, so that the force on the permanent magnet 400 is more uniform when the permanent magnet 400 is pressed.

When the permanent magnet 400 comes into contact with the boss 120, the boss 120 comes into contact with the center of the permanent magnet 400, so that the resisting force that the permanent magnet 400 receives is more uniform, effectively preventing the deviation of the permanent magnet 400.

In some embodiments, the centerline of the permanent magnet 400 deviates from the centerline of the boss 120 from each other.

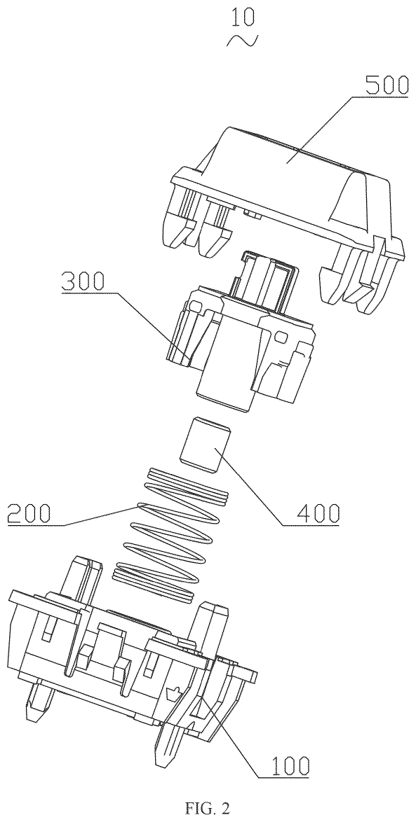

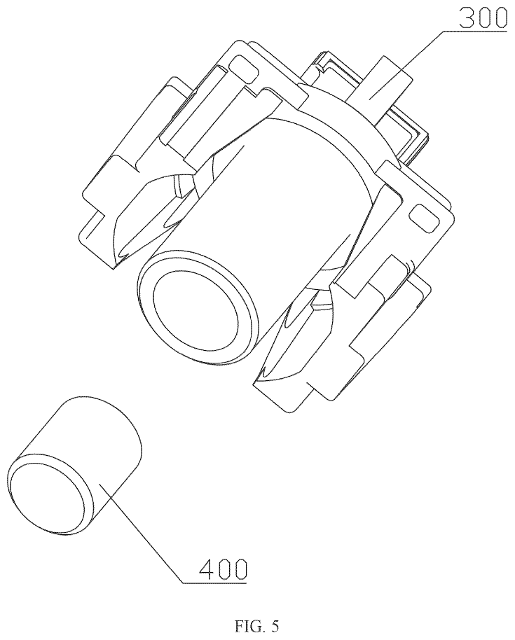

Referring to FIG. 2, FIG. 3 and FIG. 5, in order to facilitate the installation of the permanent magnet 400 on the stem 300, an installation groove is formed in the bottom of the stem 300, and the permanent magnet 400 is mounted in the installation groove. The shape of the installation groove matches the shape of the permanent magnet 400.

The permanent magnet 400 is secured in the installation groove of the stem through interference fit.

To prevent external contamination of permanent magnet 400. Referring to FIG. 3, the bottom end face of the permanent magnet 400 is located in the installation groove, and the distance from the bottom end face of the permanent magnet 400 to the bottom end face of the stem 300 is less than the thickness of the boss 120.

In some embodiments, at least one protrusion is convexly arranged on the outer surface of the bottom case 100.

In some embodiments, two protrusions are convexly arranged on the outer surface of the bottom end of the bottom case 100, the upper case 500 is connected with the bottom case 100 through a buckle structure.

### Embodiment 2

This embodiment is similar to the embodiment 1, except that the permanent magnet 400 is installed and fixed with the side wall of the installation groove by riveting.

### Embodiment 3

This embodiment is similar to the embodiment 1, except that the permanent magnet 400 is installed and fixed with the side wall of the installation groove by bonding.

### Embodiment 4

In this embodiment, two elastic blocks are arranged on the bottom end side wall of the installation groove close to the boss 120, and the elastic blocks are butting against the bottom end face of the permanent magnet 400.

The elastic blocks are bonded to the side wall of the installation groove, and the two elastic blocks are arranged oppositely. When installing the permanent magnet 400, the elastic blocks are pushed away by thrust, so that the permanent magnet 400 is installed in the installation groove. After installation, the elastic blocks are butted against the bottom end face of the permanent magnet 400, preventing the permanent magnet 400 from being separated from the installation groove.

What is claimed is:

1. A magnetic switch device, comprising a printed circuit board (PCB) and a magnetic switch, wherein the magnetic switch is connected with the PCB, the magnetic switch comprises a bottom case, an elastic member, a stem, a permanent magnet, and an upper case,
a Hall element is installed on the PCB, a bottom end of the bottom case is connected to the PCB, a guide sleeve is arranged in the bottom case, the elastic member is installed on an outer surface of the guide sleeve,
the permanent magnet is connected to a bottom end of the stem, the bottom end of the stem sliding fit with an inner surface of the guide sleeve, and the stem abuts against a top end of the elastic member, an inner surface of the bottom case corresponding to the guide sleeve is enclosed, and
the upper case is connected to the bottom case.

2. The magnetic switch device according to claim 1, wherein the upper case is provided with a hole, wherein a top end of the stem is inserted into the hole, an outer surface of the stem is in contact with the upper case through the elastic member, a boss is provided on the inner surface of the bottom case corresponding to the guide sleeve.

3. The magnetic switch device according to claim 1, wherein at least one sliding member is provided on the inner surface of the guide sleeve,
a width of the at least one sliding member on a side adjacent to the guide sleeve is wider than a width on a side away from the guide sleeve,
a cross-sectional area of a top end of the at least one sliding member is smaller than a cross-sectional area of a bottom end of the at least one sliding member,
and a number of the at least one sliding member is set to four.

4. The magnetic switch device according to claim 1, wherein an installation groove is formed in a bottom of the stem, and the permanent magnet is mounted in the installation groove.

5. The magnetic switch device according to claim 1, wherein the Hall element is welded on the PCB.

6. The magnetic switch device according to claim 1, wherein the elastic member is a spring.

7. The magnetic switch device according to claim 1, wherein the upper case is connected with the bottom case through a buckle structure,
two protrusions are arranged at the bottom end of the bottom case, and two through holes are arranged on the PCB, and each of the two protrusions is inserted into a through hole.

8. A magnetic switch device, comprising a PCB, a bottom case, an elastic member, a stem, a permanent magnet, and an upper case, wherein
a Hall element is installed on the PCB, a bottom end of the bottom case is connected to the PCB, a guide sleeve and a boss are arranged in the bottom case, the guide sleeve is configured to restrict a sliding direction of the stem, the boss is set inside the guide sleeve, the guide sleeve and the boss are spaced apart from each other, a bottom end of the elastic member is installed on an outer surface of the guide sleeve,
the permanent magnet is connected to a bottom end of the stem, the bottom end of the stem sliding fit with an inner surface of the guide sleeve, and the stem abuts against a top end of the elastic member, and
the upper case is connected to the bottom case, and when the stem is pressed down, the permanent magnet comes into contact with the boss to make a sound.

9. The magnetic switch device according to claim 8, wherein the upper case is provided with a hole, and a top end of the stem is inserted into the hole, an outer surface of the stem is in contact with the upper case through the elastic member, a width of a top of the boss is less than a width of a bottom of the boss.

10. The magnetic switch device according to claim 8, wherein the boss is set in one of shapes of a circular truncated cone, a cylinder, a cone, a cube, and a pyramid.

11. The magnetic switch device according to claim 8, wherein at least one sliding member is provided on the inner surface of the guide sleeve,
a width of the at least one sliding member on a side adjacent to the guide sleeve is wider than a width on a side away from the guide sleeve,
a cross-sectional area of a top end of the at least one sliding member is smaller than a cross-sectional area of a bottom end of the at least one sliding member, and
a number of the at least one sliding member is set to four.

12. The magnetic switch device according to claim 8, wherein a central line of the permanent magnet coincides with a central line of the boss.

13. The magnetic switch device according to claim 8, wherein an installation groove is formed in a bottom of the stem, and the permanent magnet is mounted in the installation groove.

14. The magnetic switch device according to claim 13, wherein a bottom end face of the permanent magnet is located in the installation groove, and a distance from the bottom end face of the permanent magnet to a bottom end face of the stem is less than a thickness of the boss.

15. A magnetic switch, comprising a bottom case, an elastic member, a stem, a permanent magnet, and an upper case, wherein
a guide sleeve is arranged in the bottom case, a bottom end of the elastic member is installed on an outer surface of the guide sleeve,
the permanent magnet is connected to a bottom end of the stem, the bottom end of the stem sliding fit with an inner surface of the guide sleeve, and the stem abuts against a top end of the elastic member, an inner surface of the bottom case corresponding to the guide sleeve is enclosed, and
the upper case is connected to the bottom case.

16. The magnetic switch according to claim 15, wherein the upper case is provided with a hole, wherein a top end of the stem is inserted into the hole, an outer surface of the stem is in contact with the upper case through the elastic member, a boss is provided on the inner surface of the bottom case corresponding to the guide sleeve.

17. The magnetic switch according to claim 15, wherein at least one sliding member is provided on the inner surface of the guide sleeve,
a width of the at least one sliding member on a side adjacent to the guide sleeve is wider than a width on a side away from the guide sleeve,
a cross-sectional area of a top end of the at least one sliding member is smaller than a cross-sectional area of a bottom end of the at least one sliding member,
and a number of the at least one sliding member is set to four.

18. The magnetic switch according to claim 15, wherein an installation groove is formed in a bottom of the stem, and the permanent magnet is mounted in the installation groove.

19. The magnetic switch according to claim 15, wherein the elastic member is a spring.

20. The magnetic switch according to claim 15, wherein the upper case is connected with the bottom case through a buckle structure,
two protrusions are arranged at a bottom end of the bottom case.
